(19) United States
(12) Patent Application Publication
(10) Pub. No.: US 2018/0350604 A1
(43) Pub. Date: Dec. 6, 2018

(54) Selective Deposition And Etching Of Metal Pillars Using AACVD And An Electrical Bias

(71) Applicant: Applied Materials, Inc., Santa Clara, CA (US)

(72) Inventors: Robert Jan Visser, Menlo Park, CA (US); Prerna Goradia, Vile Parle (W) (IN); Tapash Chakraborty, Thane (IN); Ranga Rao Arnepalli, Andhra Pradesh (IN); Darshan Thakare, Palghar (IN); Geetika Bajaj, New Delhi (IN)

(21) Appl. No.: 15/992,656

(22) Filed: May 30, 2018

Related U.S. Application Data
(60) Provisional application No. 62/512,717, filed on May 30, 2017.

(51) Int. Cl. H01L 21/288; C23C 16/448; C23C 16/06; C23F 1/00

(52) U.S. Cl. CPC H01L 21/2885; C23F 1/00; C23C 16/06; C23C 16/4486

(57) ABSTRACT

Embodiments of the disclosure relate to methods of selectively depositing or etching conductive materials from a substrate comprising conductive materials and nonconductive materials. More particularly, embodiments of the disclosure are directed to methods of using electrical bias and aerosol assisted chemical vapor deposition to deposit metal on conductive metal pillars. Additional embodiments of the disclosure relate to methods of using electrical bias and aerosol assisted chemical vapor deposition to etch metal from conductive metal pillars.

### CROSS-REFERENCE TO RELATED APPLICATIONS

This application claims priority to U.S. Provisional Application No. 62/512,717, filed May 30, 2017, the entire disclosure of which is hereby incorporated by reference herein.

### FIELD

One or more embodiments of the disclosure relate to methods for selectively depositing metal materials on metal containing substrates. Other embodiments of the disclosure relate to methods for selectively etching metal materials from metal containing substrates.

### BACKGROUND

Forming films on a substrate by chemical reaction of gases is one of the primary steps in the fabrication of modern semiconductor devices. These deposition processes include chemical vapor deposition (CVD) as well as plasma enhanced chemical vapor deposition (PECVD), which uses plasma in combination with traditional CVD techniques. Another variation of CVD is aerosol assisted chemical vapor deposition (AACVD), which uses aerosol sprays to deliver precursors to a substrate.

In an AACVD process, precursors are introduced into a substrate processing region of a substrate processing chamber. A substrate is positioned within the substrate processing region and one or more precursors are introduced as aerosol sprays into the substrate processing region to adsorb on the substrate and deposit a film.

Oxidation and reduction reactions are often used to chemically alter the precursors after they have adsorbed to the substrate surface. But these reactions typically involve the use of harsh reactants and reaction conditions. Methods are needed to promote oxidation and reduction of metal precursors on substrate surfaces without the use of harsh reactants or reaction conditions.

### SUMMARY

One or more embodiments of the disclosure are directed to a method of processing a substrate. The methods comprise providing a substrate having a conductive first surface and a non-conductive second surface. An electrical bias is applied to the substrate using a low voltage and the substrate is exposed to a metal source comprising metal salts or metal ions such that the metal source adsorbs on the substrate and is reduced to a metal on the first surface.

Additional embodiments of the disclosure are directed to methods of processing a substrate. The method comprises providing a substrate having a conductive first material and a non-conductive second material. An electrical bias is applied to the substrate using a low voltage. The substrate is exposed to a solvent such that the solvent adsorbs on the substrate. The first material is oxidized to metal ions in the presence of the solvent. The solvent and the metal ions are removed from the substrate.

Further embodiments of the disclosure are directed to methods of processing a substrate. A substrate comprising a first surface comprising copper and a second surface comprising SiO is provided. An electrical bias of less than about ±10 V at less than about 5 mA is applied to the substrate. The substrate is exposed to an aerosol spray of a metal source comprising water and NiSO₄ such that the metal source adsorbs on the substrate and is reduced to nickel metal on the first surface.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1A illustrates an exemplary substrate surface comprising conductive metal pillars in accordance with one or more embodiment of the disclosure;

FIG. 1B illustrates the substrate of FIG. 1A after a metal material has been deposited onto the metal pillars;

FIG. 2A illustrates an exemplary electronic circuit comprised of a substrate comprising a conductive material and a non-conductive material, mounted on an electrostatic chuck, a power source and a light emitting diode (LED);

FIG. 2B illustrates the electronic circuit of FIG. 2A with the power source activated. The conductive material's surface is negatively charged and attracts positive metal ions which can be reduced to form metal atoms on the conductive surface; and

FIG. 3 illustrates a schematic representation of an aerosol-assisted process in accordance with one or more embodiment of the disclosure.

### DETAILED DESCRIPTION

Some embodiments of the disclosure provide methods for selectively depositing metals on a substrate surface comprising conductive materials to form metal pillars. Additional embodiments of the disclosure provide methods for selectively removing or etching metal materials from a substrate surface comprising conductive materials.

A “substrate surface”, as used herein, refers to any portion of a substrate or portion of a material surface formed on a substrate upon which film processing is performed. For example, a substrate surface on which processing can be performed includes materials such as silicon, silicon oxide, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment or a posttreatment process to polish, etch, reduce, oxidize, hydroxylate, anneal, UV cure, e-beam cure and/or bake the substrate surface. In addition to substrate processing directly on the surface of the substrate itself, in the present disclosure, any of the substrate processing steps disclosed may also be performed on an underlayer formed on the substrate as disclosed in more detail below, and the term “substrate surface” is intended to include such underlayer as the context indicates. Thus for example, where a layer or partial layer has been deposited onto or etched from a substrate surface, the exposed surface of the newly deposited or etched layer becomes the substrate surface. Substrates may have various dimensions, such as 200 mm or 300 mm diameter wafers, as well as, rectangular or square panes. In some embodiments, the substrate comprises a rigid discrete material.

As used in this specification and the appended claims, the terms “reactive compound”, “reactive gas”, “reactive species”, “precursor”, “process gas”, “deposition gas”, “metal source”, “solvent” and the like are used interchangeably to mean a substance with a species capable of reacting with the substrate surface or material on the substrate surface in an oxidation or reduction reaction. The substrate, or portion of the substrate, is exposed to the metal source, which is introduced into a reaction zone of a processing chamber. In some embodiments, the metal source is introduced in a reaction zone of a processing chamber as an aerosolized spray.

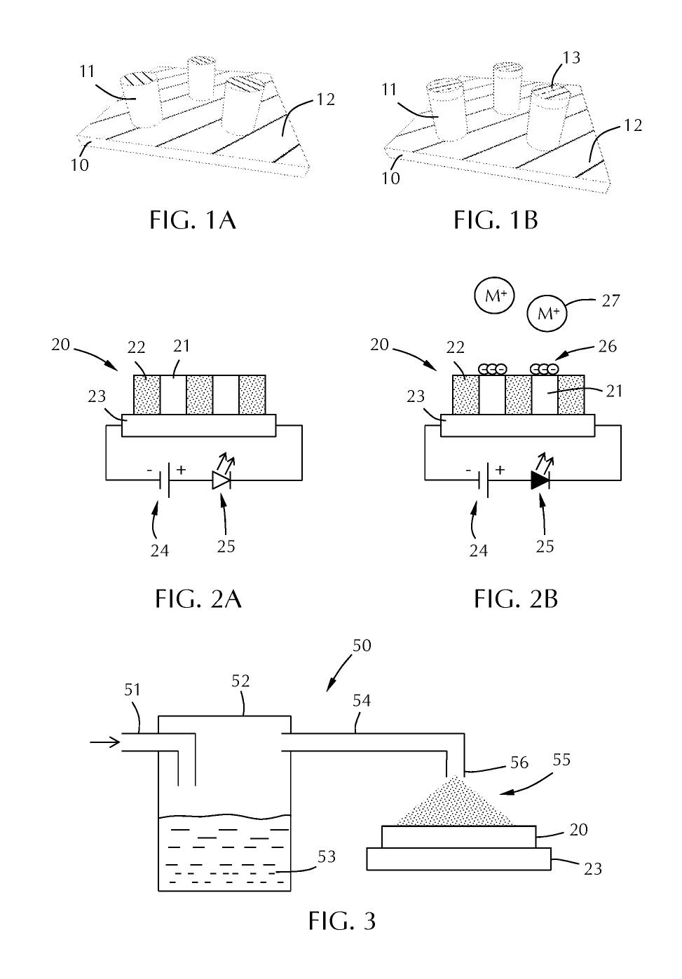

With reference to FIGS. 1A and 1B, one or more embodiments of the disclosure are directed to a method of depositing a metal on a conductive material surface. The method comprises providing a substrate 10 comprising a conductive first material 11 and a nonconductive second material 12. The substrate has an electrical bias applied using a low voltage and low current. This bias promotes a charge (either positive or negative) on the conductive first material 11. The substrate 10 is then exposed to a metal source comprising metal salts or ions which are reduced on the conductive first material 11 to form a metal 13 on the conductive first material 11.

With reference to FIG. 2, one or more embodiments of the disclosure are directed to methods of depositing a metal on a conductive material surface through the use of an electrical bias. FIG. 2A shows an electrical diagram of a substrate 20 comprising a conductive first material 21 and a nonconductive second material 22. The substrate is supported by a suitable substrate support 23 (e.g., an electrostatic chuck). A power source 24 and an LED 25 are shown connected to the substrate support 23.

As shown in FIG. 2B, in operation, the power source 24 promotes a charge 26 (shown as a negative charge) on the first conductive material 21. The charge 26 attracts and reduces positively charged metal ions 27 to metal atoms, forming a layer of metal on the surface of the first conductive material 21. While the power source 24 shown in FIG. 2B is negatively biased, those skilled in the art will understand that this is merely representative of one possible configuration. In some embodiments, the power source 24 and the conductive material 21 are positively biased.

The bias applied to the conductive material depends on, for example, the metal species being used and whether an oxidation or reduction reaction is employed. For example, if a reduction reaction is employed, the bias applied to the conductive material will be more negative than the reduction potential of the metal species. If an oxidation reaction is employed, the bias applied to the conductive material will be more positive than the reduction potential of the metal species. The absolute value of the bias applied to the conductive material can be positive or negative and still act to reduce or oxidize the target species.

In some embodiments, a metal species on the conductive material can be oxidized to remove or etch the material. This is the same type of process as that shown in FIGS. 2A and 2B in reverse. For example, the power source 24 can be biased positive of the reduction potential of the metal to be etched. A flow of solvent or chelating compounds can be included to further promote the oxidation and removal of the metal species. The thickness of a metal or metal-containing film can be reduced based on electrochemical reactions at the substrate surface.

In some embodiments, an electrical bias is applied to a substrate comprising a conductive first surface and a non-conductive second surface. The biased substrate is then exposed to a metal source comprising metal salts or metal ions so that the metal source adsorbs on the substrate and is reduced to the metal. The term “adsorbed” used in this context means that the metal source either chemically adsorbs to the material surface or is reduced upon approaching the surface and deposits the reduced metal onto the surface.

The conductive first material can be any suitable conductive material. In some embodiments, the conductive first material comprises one or more of copper, cobalt, tungsten, tantalum or titanium. In some embodiments, the conductive first surface comprises copper. In some embodiments, the conductive first surface comprises cobalt. In some embodiments, the conductive first surface comprises tungsten. In some embodiments, the conductive first surface comprises tantalum. In some embodiments, the conductive first surface comprises titanium. In some embodiments, the first conductive material comprises copper. In some embodiments, the first conductive material consists essentially of copper. In some embodiments, the first conductive material consists essentially of cobalt. In some embodiments, the first conductive material consists essentially of tungsten. In some embodiments, the first conductive material consists essentially of tantalum. In some embodiments, the first conductive material consists essentially of titanium. As used in this regard, the term “consists essentially of” means that the material surface is greater than or equal to about 95%, 98% or 99% of the stated material on an atomic basis.

The metal of the metal source can be any suitable metal species. In some embodiments, the metal source comprises a different metal than the first conductive surface. In some embodiments, the metal source comprises the same metal as the first conductive material surface. The metal source of some embodiments comprises one or more of copper, nickel, cobalt, tungsten, tantalum or titanium. In some embodiments, the metal source comprises NiSO₄.

In some embodiments, the metal source comprises a polar solvent. The polar solvent can be protic or aprotic. In some embodiments, the polar solvent is protic and comprises one or more of water, alcohols, acetic acid, formic acid, hydrogen fluoride or ammonia. In some embodiments, the polar solvent is aprotic and comprises one or more of N-methylpyrrolidone, tetrahydrofuran (THF), ethyl acetate, acetone, dimethylformamide (DMF), acetonitrile, nitromethane, dimethylsulfoxide (DMSO) or propylene carbonate.

In some embodiments, the nonconductive second surface comprises a dielectric material. The dielectric material can be high-k dielectric (dielectric constant greater than 5) or a low-k dielectric (dielectic constant less than or equal to about 5). In some embodiments, the non-conductive second material comprises one or more of an oxide, nitride, carbide, oxynitride, oxycarbide, carbonitride or oxycarbonitride species. In some embodiments, the non-conductive second material comprises silicon oxide. In some embodiments, the non-conductive second material consists essentially of silicon oxide. The skilled artisan will recognize that silicon oxide, which may be referred to as SiO or SiO₂, does not imply a particular stoichiometric ratio of silicon and oxygen atoms.

In some embodiments, the substrate is subjected to a low voltage bias. As used in this manner, the term low voltage means that the voltage applied to the substrate is within the range of −10V to +10V (also stated as ±10 V). In some embodiments, the low voltage bias is ±8V, ±6 V, ±4 V or ±2V.

The current applied to the substrate can be any suitable current that does not significantly damage any components on the substrate. As used in this manner, the term “significantly damage” means that damage occurs to less than or equal to about 5%, 2%, 1% or 0.5% of the surface components. In some embodiments, the electrical bias is provided with a current less than or equal to about 1 A, 500 mA, 250 mA, 100 mA or 50 mA. In some embodiments, the electrical bias is provided with a current of less than about 10 mA. In some embodiments, the electrical bias is provided with a current of less than about 9 mA, 8 mA, 7 mA, 6 mA, 5 mA, 4 mA, 3 mA or 2 mA. In some embodiments, the electrical bias has a current greater than or equal to about 0.01 mA.

In one or more embodiments, the electrical bias is provided in a non-uniform configuration. For example, the electrical bias can be a pulsed electrical bias. This may also be referred to as pulsed voltammetry (changing electrical potential) or pulsed amperometry (changing current). Pulsing can be any intentional change in one or more of the voltage, current or waveform of the electrical bias. In some embodiments, the voltage applied to the substrate is pulsed. In some embodiments, the current applied to the substrate is pulsed. In some embodiments, the waveform (e.g., square wave, sinusoidal, triangular, sawtooth) can be pulsed or altered during processing.

In some embodiments, pulsing the electrical bias allows for a deposition-etch type process in which deposition occurs under one condition and etching occurs under another condition. A deposition-etch process may provide increased selectivity for deposition on different surfaces of the substrate. In some embodiments, the substrate is pulsed between a reducing bias and an oxidizing bias. For example, a reducing bias might polarize the substrate greater than the Fermi level of the metal source molecules (negative potential relative to the reduction potential of the species) to electrochemically reduce the metal source molecules to deposit a metal film on the substrate. While an oxidizing bias polarizes the substrate below the Fermi level of the metal source molecules (positive potential relative to the reduction potential of the species) to electrochemically oxidize metal on the surface of the substrate.

In one or more embodiment, the bias applied to the substrate is pulsed so that selective deposition results from a deposition-etch type process. For example, selective deposition can be performed on a substrate with a conductive first surface and a nonconductive second surface. The negatively biased (relative to the reduction potential) portion of the pulse can deposit metal onto the substrate. The metal may deposit on both the conductive and nonconductive surfaces at different rates. The pulse can then switch to a positive bias (relative to the reduction potential) portion so that some of the deposited metal is oxidized and removed from the surface. The rate of metal oxidation on the conductive and nonconductive surfaces can be different. In some embodiments, the metal deposits faster on the conductive surface and oxidizes faster from the nonconductive surface to selectively deposit the metal film on the conductive surface relative to the nonconductive surface.

In some embodiments, a light emitting diode (LED) 25 is present in the electrical circuit to identify when the substrate is under bias, as shown in FIG. 2B. In some embodiments, there is no LED in the circuit path. In some embodiments, additional electrical components are included within the electrical circuit. Without limitation, these components may include resistors, variable resistors, capacitor, variable capacitors, fuses, switches and the like.

Referring to FIG. 3, some embodiments incorporate an aerosol generator 50 is used to form droplets from a condensed matter (liquid or solid) of the metal source and/or solvent. A carrier gas is flowed through an inlet 51 into an ampoule 52 or container holding the metal source 53. The carrier gas pushes metal source 53 molecules through an outlet 54 into a processing station where an aerosol 55 is directed toward a substrate 20 placed. An inline mechanical pump connected with the aerosol generator 50 can also be used to push the droplets towards the substrate. After optionally passing through a spray nozzle 56 or other droplet size-reducing element, the droplets pass into the substrate processing region and adsorb onto and react with the substrate to deposit or etch metals onto or from the conductive substrate surface.

The embodiments described herein may involve a solid precursor and/or a liquid precursor. Liquids and solids (or the combination) may generally be described as condensed matter. Condensed matter consists of atoms/molecules which are constantly under the influence of the forces imparted by neighboring atoms/molecules and may be defined as matter having essentially no or no mean free path according to embodiments. A solid precursor having low vapor pressure may be dissolved in a single solvent or mixture of compatible solvents, in embodiments, and the combination may be referred to as condensed matter. An aerosol is formed from the condensed matter and may be formed using an ultrasonic humidifier. The ultrasonic humidifier may have a piezoelectric transducer that can be operated at one or more frequencies. The ultrasonic humidifier may generate aerosol droplets which are carried into the reaction chamber (substrate processing region) using a carrier gas such as nitrogen (N₂) or argon (Ar). The carrier gas may be inert and not form covalent chemical bonds with the condensed matter nor with the substrate. An inline mechanical pump connected with the aerosol generator can also be used to push the droplets towards the substrate.

The aerosol droplets may pass through conduit(s) which are heated to prevent condensation or to promote reaction with a substrate after the aerosol droplets enter the substrate processing region. The substrate processing region resides within a substrate processing chamber and may be a vacuum chamber which is evacuated of atmospheric gases prior to delivery of the aerosol into the substrate processing region. The substrate processing region may be sealed from the external atmosphere and may be operated at much lower than atmospheric pressure to evacuate the atmospheric gases in select embodiments. The condensed matter precursors do not need to be volatile to generate the aerosol droplets. The condensed matter precursors may be soluble in a solvent or mixture of solvents from which aerosol droplets are generated.

In some embodiments, the metal source is aerosolized to provide an aerosol spray of the metal source. In these embodiments the aerosol spray is applied to the substrate in order to expose the substrate to the metal source. In some embodiments, the conductive first surface comprises metal pillars on the substrate. In these embodiments, the metal reduced on the first conductive surface is anisotropically situated in the direction of the aerosol spray.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate. For example, in some embodiments, a layer comprising a metal, a nitride, an oxide, or the like, or combinations thereof may be disposed on the substrate.

A “pulse” or “dose” as used herein is intended to refer to a quantity of a process gas, carrier gas or aerosol spray that is intermittently or non-continuously introduced into the process chamber. The quantity of a particular compound within each pulse may vary over time, depending on the duration of the pulse. A particular process gas may include a single compound (e.g. a metal source) or a mixture/combination of two or more compounds (e.g. a metal source and a solvent).

The durations for each pulse/dose are variable and may be adjusted to accommodate, for example, the volume capacity of the processing chamber or the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/react onto substantially the entire surface of the substrate and form a layer of a process gas component thereon.

The period of time that the substrate is exposed to the process gas may be any suitable amount of time necessary to allow the metal source to form an adequate nucleation layer atop the substrate surfaces. For example, the process gas may be flowed into the process chamber for a period of about 1 second to about 500 seconds.

In some embodiments, a carrier gas may additionally be provided to the process chamber at the same time as the aerosol spray. The carrier gas may be mixed with the metal source or solvent (e.g., as a diluent gas) or separately and can be pulsed or of a constant flow. In some embodiments, the inert gas is flowed into the processing chamber at a constant flow in the range of about 1 to about 10000 sccm. The inert gas may be any inert gas, for example, such as argon, helium, neon, combinations thereof, or the like.

In addition to the foregoing, additional process parameters may be regulated while exposing the substrate to the metal source and/or solvent. For example, in some embodiments, the process chamber may be maintained at a certain pressure or at a certain temperature to facilitate the deposition or etching of the metal.

After a predetermined amount of metal has been deposited or etched, a posttreatment reaction may occur. Suitable reactants for post treatment include, but are not limited to, H₂, NH₃, hydrazine, hydrazine derivatives and other co-reactants to make MₓN_{y} films. Suitable reactants may also include, but are not limited to, 0₂, 0₃, water and other oxygen based co-reactants to make MₓO_{y} films. Post treatments may also be combined to produce oxynitride metal surfaces. Other suitable reactants for post treatment include a compound selected to form a metal silicide, metal silicate, metal carbide, metal carbonitride, metal oxycarbide, metal oxycarbonitride, or a metal film including one or more of O, N, C, Si or B. Plasma treatments of a reactant as a posttreatment may also be used.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of processing a substrate, the method comprising:
providing a substrate comprising a conductive first surface and a non-conductive second surface;
applying an electrical bias to the substrate using a low voltage; and
exposing the substrate to a metal source comprising metal salts or metal ions such that the metal source adsorbs on the substrate and is reduced to a metal on the conductive first surface.

2. The method of claim 1, wherein the conductive first surface comprises one or more of copper, cobalt, tungsten, tantalum or titanium.

3. The method of claim 1, wherein the conductive first surface comprises copper.

4. The method of claim 1, wherein the non-conductive second surface comprises silicon oxide.

5. The method of claim 1, wherein the low voltage is less than about ±10V.

6. The method of claim 1, wherein the electrical bias is provided with a current of less than about 10 mA.

7. The method of claim 1, wherein the electrical bias is provided with a current of less than about 5 mA.

8. The method of claim 1, further comprising aerosolizing the metal source to provide an aerosol spray of the metal source.

9. The method of claim 1, wherein the metal source comprises a polar solvent.

10. The method of claim 9, wherein the polar solvent comprises one or more of water, alcohols, formic acid, acetic acid, nitromethane, hydrogen fluoride or ammonia.

11. The method of claim 10, wherein the metal source comprises water.

12. The method of claim 1, wherein the metal source comprises NiSO₄.

13. A method of processing a substrate, the method comprising:
providing a substrate comprising a conductive first material and a non-conductive second material;
applying an electrical bias to the substrate using a low voltage;
exposing the substrate to a solvent such that the solvent adsorbs on the substrate;
oxidizing the conductive first material to form metal ions in the presence of the solvent; and
removing the solvent and the metal ions from the substrate.

14. The method of claim 13, wherein the conductive first material comprises one or more of copper, cobalt, tungsten, tantalum or titanium.

15. The method of claim 13, wherein the non-conductive second material comprises Silicon oxide.

16. The method of claim 13, wherein the electrical bias is provided with a current of less than about 5 mA.

17. The method of claim 13, wherein the substrate is exposed to an aerosol spray of the solvent.

18. The method of claim 13, wherein the solvent comprises a polar solvent.

19. The method of claim 18, wherein the solvent comprises water.

20. A method of processing a substrate, the method comprising:
providing a substrate comprising a first surface comprising copper and a second surface comprising Silicon oxide;
applying an electrical bias of less than about ±10 V at less than about 5 mA to the substrate; and
exposing the substrate to an aerosol spray of a metal source comprising water and NiSO₄ such that the metal source adsorbs on the substrate and is reduced to nickel metal on the first surface.
